(19) United States
(12) Patent Application Publication
(10) Pub. No.: US 2011/0182046 A1
(43) Pub. Date: Jul. 28, 2011

(54) ELECTRONIC CIRCUIT DEVICE, METHOD FOR MANUFACTURING THE SAME, AND DISPLAY DEVICE

(75) Inventor: Motoji Shiota, Osaka (JP)

(73) Assignee: SHARP KABUSHIKI KAISHA, Osaka (JP)

(21) Appl. No.: 13/001,033

(22) PCT Filed: Apr. 14, 2009
(86) PCT No.: PCT/JP2009/057486

§ 371 Date: Dec. 22, 2010

(30) Foreign Application Priority Data
Jul. 22, 2008 (JP) 2008-188636

(51) Int. Cl. H05K 7/00; H05K 3/30

(52) U.S. Cl. 361/760; 361/783; 156/297

(57) ABSTRACT

The present invention provides a reduced size electronic circuit device, a manufacturing method of the same, and a display device having the same made by the manufacturing method. The electronic circuit device of the present invention is an electronic circuit device, wherein a first electronic component and a second electronic component are respectively connected electrically to a third electronic component; the first electronic component is bonded to the third electronic component through a first adhesive layer; the second electronic component is bonded to the third electronic component through the first and second adhesive layers; and one of the first adhesive layer and the second adhesive layer contains an anisotropic conductive material and the other adhesive layer does not contain the anisotropic conductive material.

### TECHNICAL FIELD

The present invention relates to an electronic circuit device, a method for manufacturing the same, and a display device having the same made by the manufacturing method. More particularly, the present invention relates to an electronic circuit device, wherein a plurality of electronic components are connected and bonded to each other through adhesive materials such as an anisotropic conductive material, a method for manufacturing the electronic circuit device, and a display device having the electronic circuit device made by the manufacturing method.

### BACKGROUND ART

An anisotropic conductive material has been used as an adhesive material for connecting and bonding together electronic components having numerous opposing electrodes. Anisotropic conductive material is a connection material that connects electronic components electrically by maintaining conductivity between opposing electrodes while maintaining insulation between neighboring electrodes, and also mechanically bonds electronic components together. By using the anisotropic conductive material, semiconductor elements such as semiconductor integrated circuits (hereinafter may be referred to as “IC”) and large-scale integrated circuits (hereinafter may be referred to as “LSI”) can be mounted on the wiring substrates such as printed circuit substrates or substrates that constitute a liquid crystal display panel.

Described here is the conventional technology of mounting ICs and Flexible Printed Circuit substrates (hereinafter may be referred to as “FPC substrate”) on glass substrates constituting a liquid crystal display panel. FIG. 5 is a schematic view of a mounting structure in a conventional liquid crystal display panel, wherein (a) is a schematic isometric view and (b) is a cross-sectional view taken along the line P-Q of FIG. 5(a). As shown on FIG. 5, in a conventional liquid crystal display panel 36, driving IC 28 and FPC substrate 30 are mounted on a projected portion 22 of glass substrate (TFT array substrate) 39a, one of the glass substrates that constitute the liquid crystal panel 36. More specifically, glass substrate 39a has circuit wirings 23 and 24 on projected portion 22 on the side towards driving IC 28 and FPC substrate 30. Driving IC 28 has bump electrodes 29 on the side towards glass substrate 39a. FPC substrate 30 has base material 32 and lead electrode 31, the lead electrode being formed on base material 32 on the side towards glass substrate 39a. On glass substrate 39a, anisotropic conductive layer 33a, which is made by hardening an anisotropic conductive material, is located in the area containing circuit wirings 23 and 24, and anisotropic conductive layer 33b, which is made by hardening an anisotropic conductive material, is located in the area containing circuit wiring 24. Anisotropic conductive layers 33a and 33b are, for example, epoxy resin having conductive particles 34a and 34b dispersed respectively. Anisotropic conductive layers 33a and 33b are conductive in the direction of thickness, and insulating in the direction of plane. Using the anisotropic conductive material, bump electrodes 29 of driving IC 28 are electrically connected to circuit wirings 23 and 24 through conductive particles 34a, and driving IC 28 is bonded to glass substrate 39a by the resin contained in anisotropic conductive layer 33a. On the other hand, lead electrodes 31 of FPC substrate 30 are electrically connected to circuit wiring 24 through conductive particles 34b contained in anisotropic conductive layer 33b, and FPC substrate 30 is bonded to glass substrate 39a by the resin contained in anisotropic conductive layer 33b.

A method of manufacturing the aforementioned conventional liquid crystal display panel 36 is described below. First, liquid crystal display panel 36 in which circuit wirings 23 and 24 are formed on glass substrate 39a (liquid crystal 38 is sealed between glass substrates 39a and 39b by sealing member 37) is prepared. Next, anisotropic conductive material (anisotropic conductive layer 33a before being hardened) such as anisotropic conductive film (hereinafter may be referred to as “ACF”) is applied in the plane of glass substrate 39a over the area containing circuit wirings 23 and 24. Circuit wirings 23 and 24 and bump electrodes 29 of driving IC 28 are aligned, then driving IC 28 is bonded to circuit wirings 23 and 24 by thermal compression under a predetermined condition. Next, in a similar manner, anisotropic conductive material (anisotropic conductive layer 33b before being hardened) such as ACF is applied over the area containing circuit wiring 24, and FPC substrate 30 is bonded to circuit wiring 24 by thermal compression. In this way, external circuits such as driving IC 28 and FPC substrate 30 are mounted to liquid crystal panel 36.

In recent years, there is an increased demand for space-saving features in electronic devices such as televisions, personal computer displays and displays of portable terminal devices. To meet this demand, a further size reduction of area other than the display area is necessary. Such size reduction requires smaller mounting area (frame area) for external circuits such as driving IC and flexible printed circuit substrate.

In conventional liquid crystal display panel 36, however, anisotropic conductive layers 33a and 33b are disposed over the areas larger than the actual mounting areas of driving IC 28 and FPC substrate 30 in order to accommodate any imprecision in positioning when driving IC 28 and FPC substrate 30 are mounted. Another issue is that if an ACF for connection with other components is inserted under the mounting region of respective components, imbalance in bonding pressure may occur, resulting in defective compression bonding. Also, any partial overlapping of ACFs, even if not taking place under the mounting regions of components, can cause poor attachment due to application of uneven pressure. Therefore, anisotropic conductive layers 33a and 33b need to be positioned away from each other. Considering the achievable precision in positioning individual anisotropic conductive layers 33a and 33b, a minimum distance (space), A2, must be provided between driving IC 28 and FPC substrate 30 (at least 0.4 mm, for example). That is, in order to apply different adhesive layers, such as anisotropic conductive layers 33a and 33b, on a single member, a sufficiently large area must be secured for applying the respective adhesive layers. This problem with conventional liquid crystal display panel 36 sets a limitation on the possibility in reduction of the frame area.

In a quest for higher productivity, simplified manufacturing process and higher yield rate, technologies addressing the shared use of the same ACF for mounting external circuits such as driving IC and FPC substrate have been disclosed.

More specifically, an electrooptical device in which integrated circuit chips are conductively connected by an anisotropic conductive film to the wiring pattern, and the anisotropic conductive film is formed to cover the connection wiring area has been disclosed (e.g., see Patent Document 1).

Also disclosed is a display device wherein a first member and a second member are mounted to at least one of the substrates constituting a display panel via a common anisotropic conductive film (e.g., see Patent Document 2).

Another disclosure is a method for panel mounting, having the process of applying an anisotropic conductive material over a closed area on a panel on which circuit wirings are formed, which closed area contains multiple sites for mounting multiple components, and the process of bonding the circuit wirings and the components together via the anisotropic conductive material by thermal compression (e.g., see Patent Document 3).

The problem is that the each external circuit (components to be mounted) has different properties. Driving IC and FPC substrate, for example, are different in hardness (hard or soft) and in materials used (silicone material or polyimide film). This fact makes it difficult to develop an anisotropic conductive film that can be shared by multiple external circuits including different electrical components. In other words, conventional ACF shared by multiple components might provide sufficient conductivity and bonding for certain components, but may not provide sufficient conductivity and bonding for other components. Therefore, the conventional technology needs to be improved for mounting structures with higher reliability.

An integrated adhesive sheet in which multiple adhesive sheets are connected together for mounting multiple kinds of circuit substrates on a single substrate has been disclosed (e.g., see Patent Document 4). Using this technology, ACF for driving IC and ACF for FPC substrate can be formed as a single piece. However, there are technological and cost issues in the production of this adhesive sheet. Also, placement of the adhesive sheet requires higher precision.

Another disclosure is a liquid crystal display device that has an anisotropic conductive film for connecting the integrated driving circuits to the panel connection electrode and the external circuit connection pattern electrode, and has a flexible printed circuit substrate mounted on the back of the integrated driving circuits by a thermosetting anisotropic conductive film, wherein the flexible printed circuit substrate is connected to the external circuit connection pattern electrode via the conductive pattern along the side wall of the integrated driving circuit (e.g., see Patent Document 5). This disclosure indicates that the technology described can shorten the length of the external circuit connection pattern electrode. However, it is technically very difficult to produce this kind of liquid crystal display device. In this liquid crystal display device, the ACF used to connect the external circuit connection pattern to the integrated driving circuit is not present between the back side pattern and the flexible printed circuit substrate.

Also disclosed is a technology that reduces the external dimension of the display panel by using a conductive member such as an anisotropic conductive material for connecting the display panel to an FPC and the FPC to the wiring substrate (e.g., see Patent Document 6). This technology, however, relates to TCP (Tape Carrier Package) technology. The technology does not reduce the size of the panel (substrate), and therefore needs further innovation for size reduction of the mounting area (frame area).

In another disclosed technology employing an anisotropic conductive film, all the scan electrodes and signal electrodes in a liquid crystal panel having three liquid crystal layers are electrically connected to the external electrode substrate via an anisotropic conductive film (e.g., see Patent Document 7).

Another disclosure is a method of interconnecting semiconductor elements using an anisotropic conductive film, including the step of transferring an anisotropic conductive film to electrodes of both semiconductor elements to be connected together in such a way to form a gradient in the film thickness across each electrode, and the step of bonding the two semiconductor elements together so that the gradient of the anisotropic conductive film thickness is eliminated (e.g., see Patent Document 8).

Also disclosed is a laminate body containing multi-layered anisotropic conductive films, wherein the peel-off film does not contain silicon, and has a tensile strength of 10 kN/cm² or more and the surface tension of 350 μN/cm² or less; the first anisotropic conductive film, which is in contact with the top surface of the peel-off film, has a peel force of 2 N/5 cm or less; and the second anisotropic conductive film, which is in contact with the back surface of the peel-off film, has a peel force that is less than the peel force of the first anisotropic conductive film by 0.05 N/5 cm or more (e.g., see Patent Document 9). In this disclosure, ACFs of different peel forces from the peel-off film are layered on top of the other, and they are supplied together as a laminate body. This laminate body having multi-layered anisotropic conductive films helps prevent any blocking that otherwise might take place during ACF rewinding and maintains a reliable peel force of the ACF.

### Related Art

### Patent Documents

Patent Document 1: Japanese Patent Application Laid-Open Publication No. 2001-242799

Patent Document 2: Japanese Patent Application Laid-Open Publication No. 2002-305220

Patent Document 3: Japanese Patent Application Laid-Open Publication No. H05-313178

Patent Document 4: Japanese Patent Application Laid-Open Publication No. 2006-56995

Patent Document 5: Japanese Patent Application Laid-Open Publication No. H09-101533

Patent Document 6: Japanese Patent Application Laid-Open Publication No. 2000-347593

Patent Document 7: Japanese Patent Application Laid-Open Publication No. H10-228028

Patent Document 8: Japanese Patent Application Laid-Open Publication No. H10-145026

Patent Document 9: Japanese Patent Application Laid-Open Publication No. 2001-171033

### SUMMARY OF THE INVENTION

### Problems to be Solved by the Invention

The present invention was devised in consideration of the current situation in the field as described above, and is aiming at providing a reduced size electronic circuit device, a method for manufacturing the same, and a display device having the same made by the manufacturing method.

### Means of Solving the Problems

In the quest of devising a smaller electronic circuit device, a manufacturing method of the same and a display device having the same made by the manufacturing method, the inventors of the present invention focused on ways in which adhesive layers including an anisotropic conductive layer are disposed. The inventors found that the electronic circuit device can be made smaller by employing a configuration in which a first electronic component is bonded to a third electronic component through a first adhesive layer; a second electronic component is bonded to the third electronic component through the first adhesive layer and a second adhesive layer, wherein the first and second adhesive layers are applied in this order on the third electronic component; and one of the first adhesive layer and the second adhesive layer contains an anisotropic conductive material and the other does not contain an anisotropic conductive material. As a result, the above-mentioned problems have been admirably solved, leading to the present invention.

More specifically, the present invention is an electronic device in which the first electronic component and the second electronic component are respectively connected electrically to the third electrical component, wherein the first electronic component is bonded to the third electronic component through the first adhesive layer and the second electronic component is bonded to the third electronic component through the first and second adhesive layers, and one of the first adhesive layer and the second adhesive layer contains an anisotropic conductive material and the other does not contain an anisotropic conductive material. This configuration allows the first and second electronic components to be respectively connected to the third electronic component electrically with less required precision in positioning the adhesive materials for the first and second adhesive layers in the manufacturing process. Less required precision allows for a narrower distance between the first and second electronic components, which reduces the size of the electronic circuit device. Moreover, at least one of the first and second electronic components can be electrically connected to the third electrical component easily since at least one of the first and second adhesive layers contains the anisotropic material. Also, the manufacturing cost can be lowered and the film thickness can be reduced since the other of the first and second adhesive layers is a non-conductive layer that does not contain an anisotropic conductive material.

Normally, the first adhesive layer is applied over the area where the first electronic component and the third electronic component meet, and the area where the second electrical component and the third component meet. On the other hand, normally, the second adhesive layer is applied over the area where the second electronic component and the third electronic component meet. Thus, the first adhesive layer is preferably applied to cover at least the area where the first electronic component and the third electronic component meet and the area where the second electronic component and the third electronic component meet. And, the second adhesive layer is preferably applied to cover at least the area where the second electronic component and the third electronic component meet, excluding the area where the first electronic component and the third electronic component meet.

The present invention may be an electronic circuit device having three or more electronic components, wherein a first electronic component and a second electronic component are respectively connected to a third electronic component; the first electronic component and the second electronic component are bonded to the third electronic component through an adhesive layer having a laminated structure of a first adhesive layer, which is located on the side of the third electronic component in the direction of the thickness, and a second adhesive layer, which is located on the side of the second electronic component in the direction of the thickness, wherein the first adhesive layer is disposed to cover the disposed (mounting) areas of the first electronic component and the second electronic component, and the second adhesive layer is disposed to cover the disposed (mounting) area of the second electronic component. The present invention may also be an electronic circuit device comprising three or more electronic components, wherein a first electronic component and a second electronic component are respectively connected to a third electronic component; the first electronic component and the second electronic component are bonded to the third electronic component through an adhesive layers having a laminated structure of a first adhesive layer, which is located on the side of the third electronic component in the direction of the thickness, and a second adhesive layer, which is located on the side of the second electronic component in the direction of the thickness, wherein the first adhesive layer is disposed to cover at least the disposed (mounting) areas of the first electronic component and the second electronic component, and the second adhesive layer is disposed to cover at least the disposed (mounting) area of the second electronic component, excluding the disposed (mounting) area of the first electronic component.

The aforementioned first to third electronic components may be active elements, passive elements (chip components), packages of integratedly mounted passive devices, or wiring substrates (circuit substrates). Active elements may be semiconductor devices, such as semiconductor integrated circuits (IC) or large-scale integrated circuits (LSI). Passive elements may be LEDs (Light Emitting Diodes), capacitors or sensors. More specifically, wiring substrates may be PWBs (Printed Wiring Board), printed circuit substrates such as FPC substrates, or substrates constituting a display panel such as liquid crystal display panel. In other words, wiring substrates normally are electronic components wherein wiring is installed on and/or inside an insulating substrate (base member). A PWB may be a PCB (Printed Circuit Board).

The configuration of the electronic circuit device of the present invention is not particularly limited; as long as the electronic circuit device has the constituent elements listed above as essential items, other constituent elements may or may not be included. Preferred embodiments of the electronic circuit of the present invention are described in detail below. Embodiments described below may be combined.

The adhesive layer containing the anisotropic conductive material is not particularly limited; it may be the first adhesive layer or the second adhesive layer. More specifically, in a possible embodiment, the first adhesive layer contains the anisotropic conductive material and the second adhesive layer does not contain the anisotropic conductive material. In this embodiment, the first electronic component and the second electronic component are respectively electrically connected to the third electronic component securely by the anisotropic conductive material contained in the first adhesive layer. Thus, it is preferable that the first adhesive layer contains the anisotropic conductive material and the second adhesive layer does not contain the anisotropic conductive material, and the first electronic component and the second electronic component are respectively electrically bonded to the third electronic component by the anisotropic conductive material in the first adhesive layer. In another embodiment, the first adhesive layer does not contain the anisotropic conductive material and the second adhesive layer contains the anisotropic conductive material. In this embodiment, the second electronic component is electrically connected to the third electronic component securely by the anisotropic conductive material contained in the second adhesive layer. Thus, it is preferable that the first adhesive layer does not contain the anisotropic conductive material and the second adhesive layer contains the anisotropic conductive material, and the second electronic component is electrically connected to the third electronic component by the anisotropic conductive material in the second adhesive layer. In this case, the first electronic component and the third electronic component can be electrically connected, for example, by an Au—Sn eutectic.

The kind of the first and second electronic components is not particularly limited, but the first and second electronic components are preferably of different kinds Previously, it was very difficult to narrow the mounting distance between two different components. However, the present invention makes it possible to reduce the size of the electronic circuit device even if the first and second electronic components that are of different kinds are mounted on the third electronic component. The effect of the present invention therefore is especially evident for this type of device.

The kind of the third electronic component is not especially limited, but the third electronic component is preferably a wiring substrate. Preferably, the electronic circuit device of the present invention has a configuration wherein at least two electronic components are mounted on a wiring substrate (the third electronic component).

When the electronic circuit device of the present invention is used as a controller for a display device such as a liquid crystal display device, the first and second electronic components are preferably a pair of an active element and a printed circuit substrate, and the third electronic component is preferably a wiring substrate. The frame area of a display device can be narrowed by such configuration. More specifically, the first electronic component and the second electronic component are preferably a pair of a semiconductor element and a flexible printed circuit substrate, and the third electronic component is preferably a substrate that constitutes a part of a panel. In this embodiment of the electronic circuit device of the present invention, the first electronic component may be a semiconductor element and the second electronic component may be a flexible printed circuit substrate, or the first electronic component may be a flexible printed circuit substrate and the second electronic component may be a semiconductor element.

The first electronic component preferably has surface properties different from the second electronic component. Conventionally, it was difficult to share an adhesive material such as anisotropic conductive material for mounting two electronic components with different surface properties. In the present invention, however, materials of different properties and/or forms can be selected for the first and second adhesive layers; therefore the first and second electronic components can be mounted by the first and second adhesive materials having suitable properties for the components. This aspect of the present invention improves the reliability of the electronic circuit device, in particular when the first and second electronic components having different surface properties are mounted on the third electronic component. Having different surface properties means, more specifically, being different in at least any one of the following properties preferably: adhesion with the first and second adhesive layers, surface profile and surface material type.

Preferably, the first adhesive layer and the second adhesive layer individually contain different kinds of adhesive ingredients. This way, the properties of the first and second adhesive layers can be modified to best fit the type and surface properties of the first and second electronic components. In other words, the first adhesive layer can contain an adhesive ingredient that provides proper adhesion with the first electronic component, and the second adhesive layer can contain an adhesive ingredient that provides proper adhesion with the second electronic component. As a result, the first and second electronic components are bonded to the third electronic components more securely, which improves the reliability of the electronic circuit device. The component of adhesive ingredients is not particularly limited as long as the component exhibits adhesive properties, but resin is preferred, and thermosetting resin is especially preferred.

The properties and forms of the first and second adhesive layers are not particularly limited, but the first and second adhesive layers preferably have different storage elastic moduli. This way, the first and second adhesive layers having proper adhesion for bonding the first and second electronic components to the third electronic component can be used. The reliability of the electronic circuit device is thus improved. More specifically, the first adhesive layer is preferably a combination of an adhesive layer having a storage elastic modulus of 1.5 to 2.0×10⁹ Pa and another adhesive layer having a storage elastic modulus of 1.2 to 1.3×10⁹ Pa. The adhesive layer with a storage elastic modulus of 1.5 to 2.0×10⁹ Pa is suitable as an adhesive layer for active elements, in particular semiconductor elements. The adhesive layer with storage elastic modulus of 1.2 to 1.3×10⁹ Pa is suitable as an adhesive layer for printed circuit substrates, in particular FPC substrates. An electronic circuit device having such adhesive layers therefore is suitable as a controller for a display device. With an adhesive layer having a storage elastic modulus of less than 1.5×10⁹ Pa or more than 2.0×10⁹ Pa, active elements, in particular semiconductor elements, may not be securely mounted to the third electronic components. Also, printed circuit substrates, in particular FPC substrates may not be securely mounted to the third electronic components when an adhesive layer having storage elastic modulus of less than 1.2×10⁹ Pa or more than 1.3×10⁹ Pa. The electronic circuit device of the present invention may have the first adhesive layer with a storage elastic modulus of 1.5 to 2.0×10⁹ Pa and the second adhesive layer with a storage elastic modulus of 1.2 to 1.3×10⁹ Pa.

When the present invention is used as a controller for a display device, preferably the first electronic component is a semiconductor element and the second electronic component is a flexible printed circuit substrate, and the third electronic component is a substrate that constitutes a part of a display panel, wherein the first adhesive layer has a storage elastic modulus of 1.5 to 2.0×10⁹ Pa and the second adhesive layer has a storage elastic modulus of 1.2 to 1.3×10⁹ Pa.

Forms for the first and second adhesive layers (the first and second adhesive materials) are not particularly limited, and possible materials include paste (liquid) adhesives (non-conductive paste; NCP) and film adhesives (non-conductive film; NCF). Possible forms of anisotropic conductive materials for the first and second adhesive layers include paste (liquid) anisotropic conductive material (anisotropic conductive paste; ACP) and film anisotropic conductive material (anisotropic conductive film; ACF). For manufacturing process simplification and fine pitch wiring, however, the adhesive layers are preferably formed from film adhesive materials. That is, preferably, at least one of the first adhesive layer and the second adhesive layer is formed from a film material, and more preferably, both the first adhesive layer and the second adhesive layer are formed from film materials. The planar shapes of the first and second adhesive layers are not particularly limited, but preferably the planar shapes are a polygon wherein each side bisects with another at approximately a right angle, and more preferably, the planar shape is approximately rectangular from a standpoint of simplifying the manufacturing purposes.

The first adhesive layer preferably has a larger thickness than the second adhesive layer. The first electronic component needs to be electrically connected (hereinafter may be simply referred to as “connected”) to the third electronic component securely, and the second electronic component needs to be securely connected to the third electronic component. If the thickness of the first adhesive layer is set to the appropriate thickness of the conventional first adhesive layer, i.e., the adhesive layer used solely for bonding the first electronic component to the third electronic component, and the thickness of the second adhesive layer is set to the appropriate thickness of the conventional second adhesive layer, i.e., the adhesive layer used solely for bonding the second electronic component to the third electronic component, the thickness of the adhesive material (the first and second adhesive materials) applied between the second and the third electronic components in the present invention would be too large, causing insufficient spread (insufficient push), which might lead to a poor connection between the second and the third electronic components. For this reason, preferably the thicknesses of the first and second adhesive materials, that is, the thicknesses of the first and second adhesive layers, are adjusted for a better balance in the present invention. More specifically, poor connections between the second and the third electronic components can effectively be prevented by reducing the thickness of the second adhesive layer below the thickness of the first adhesive layer, as stated above. In this way, a better connection is established between the second and the third electronic components.

The present invention is also a manufacturing method for the aforementioned electronic circuit device, which method includes the steps of applying a first adhesive material on the third electronic component to cover the mounting areas of the first electronic component and the second electronic component (first application process); applying a second adhesive material to cover the mounting area of the second electronic component on the third electronic component, or to cover an area on the second electronic component to be affixed to the third electronic component (second application process); compression-bonding the first electronic component to the third electronic component through the first adhesive material (first compression bonding process); and compression-bonding the second electronic component to the third electronic component (second compression bonding process). This method eliminates the need for the high precision positioning of the first and second adhesive materials. Less required precision allows for a narrower distance between the first and second electronic components, which results in a size reduction of the electronic circuit device.

The present invention may also be another manufacturing method for the aforementioned electronic circuit device, which method includes the steps of applying a first adhesive material on the third electronic component to cover at least the mounting areas of the first electronic component and the second electronic component (first application process); applying a second adhesive material to cover at least the mounting area of the second electronic component on the third electronic component, excluding the mounting area of the first electronic component, or to cover at least the area to be bonded to the third electronic component on the second electronic component (second application process); compression-bonding the first electronic component to the third electronic component through the first adhesive material; and compression-bonding the second electronic component to the third electronic component through the first adhesive material and the second adhesive material.

The method for manufacturing of the electronic circuit of the present invention does not particularly limit processes other than those described above, as long as the method includes processes described above. Normally, the second application process is conducted after the first application process.

Preferred embodiments of the manufacturing method of the electronic circuit of the present invention are described in detail below. Embodiments described below may be combined.

The aforementioned first compression bonding process is preferably the first thermal compression bonding process wherein the first electronic component is bonded to the third electronic component by thermal compression through the first adhesive material; and the aforementioned second compression bonding process is preferably the second thermal compression bonding process wherein the second electronic component is bonded to the third electronic component by thermal compression through the first adhesive material and the second adhesive material. This embodiment allows the first electronic component to be securely connected to the third electronic component, and the second electronic component to be securely connected to the third electronic component under a proper condition, wherein each connection is made in a short time.

The first thermal compression bonding process and the second thermal compression bonding process are preferably conducted consecutively. If another process is performed between the first thermal compression bonding process and the second thermal compression bonding process, the area on the first adhesive material to which the first electronic component or the second electronic component is to be bonded in the later thermal compression bonding might be hardened by the heat from the earlier thermal compression bonding. By conducting the first thermal compression bonding and the second thermal compression bonding consecutively, the area on the first adhesive material to which the first electronic component or the second electronic component is to be bonded in the later thermal compression bonding remains unhardened. Thus, in the above-mentioned manufacturing process of the electronic circuit device, either the first thermal compression bonding process or the second thermal compression bonding process, whichever performed later, is preferably performed while at least one of the first adhesive material and the second adhesive material disposed over the area to which the first electronic component or the second electronic component is to be bonded by thermal compression is still unhardened. It should be noted that the adhesive material does not have to remain perfectly unhardened; the adhesive material should remain unhardened enough to allow connection and bonding between electronic components. Preferably, however, the adhesive material remains in a stage wherein almost no hardening has yet occurred. Similarly, in the aforementioned manufacturing process for the electronic circuit device, the first thermal compression bonding process or the second thermal compression bonding process may be performed without any interruption in between; or the first thermal compression bonding process and the second thermal compression bonding process may be performed consecutively in the same compression bonding device.

The first thermal compression bonding process or the second thermal compression bonding process, whichever performed earlier, is preferably performed while the area on the third electronic component to which the first electronic component or the second electronic component is to be bonded in the first thermal compression bonding process or the second thermal compression bonding process, whichever performed later, is being cooled. If the first thermal compression bonding process and the second thermal compression bonding process are performed separately, the area on the first adhesive material to which the first electronic component or the second electronic component is to be bonded in the later thermal compression bonding process might be hardened by the heat from the earlier thermal compression bonding. However, by performing the earlier thermal compression bonding process, which may be the first thermal compression bonding process or the second thermal compression bonding process, while cooling the area on the third electronic component to which the first electronic component or the second electronic component is to be bonded during the later thermal compression bonding process, which may be the first thermal compression bonding process or the second thermal compression bonding process, the area for mounting the first or second electronic component during the later thermal compression bonding process remains unhardened with certainty. This procedure also minimizes the area on the first adhesive material that is hardened by the earlier thermal compression bonding. The electronic component that is to be mounted during the later thermal compression bonding process therefore can be positioned closer to the electronic component mounted during the earlier thermal compression bonding process, which results in size reduction of the electronic circuit device. The temperature for cooling the area on the third electronic component to which the first electronic component or the second electronic component is to be compression-bonded during the later thermal compression bonding process is not particularly limited, but the cooling temperature is preferably 90° C. or lower. If the cooling temperature is higher than 90° C., the first adhesive material is hardened excessively during the earlier thermal compression bonding process, preventing the proper thermal compression bonding of the first or the second electrical components during the later thermal compression bonding process.

The first thermal compression bonding process and the second thermal compression bonding process may be conducted simultaneously. In this case, the first electronic component and the second electronic component are bonded by thermal compression through the first adhesive material and the second adhesive material while the adhesive materials are still unhardened, meaning that the first electronic component and the second electronic component are more securely connected to the third electronic component. There is no need to cool the mounting area of the first or the second electronic component as described above, which eliminates the need for a cooling system in the thermal compression bonding device, reducing the equipment costs. Another advantage of this method is that since the first electronic component and the second electronic component can be positioned closer to each other, size reduction of the electronic circuit device is possible. The first thermal compression bonding process and the second thermal compression bonding process may be conducted simultaneously in the same compression bonding device. In this specification of the present invention, simultaneous performance of the first thermal compression bonding process and the second thermal compression bonding process does not mean that the processes need to be done strictly at the same time. Rather, the two thermal compression bonding processes may be conducted at a substantially simultaneous timing to the extent that it is realistically achievable by using the same thermal compression bonding device.

Forms that the items constituting the electronic circuit device of the present invention may take in the manufacturing process of the electronic circuit device may be those that have been described in the embodiments of the electronic circuit device of the present invention. From a standpoint similar to that for the electronic circuit device of the present invention, the first adhesive material preferably has a larger thickness than the second adhesive material.

The present invention is also a display device having the electronic circuit device of the present invention, or a display device manufactured by the manufacturing method of the electronic circuit device of the present invention. The present invention makes it possible to reduce the size of the electronic circuit device, and thereby makes the frame area of the display device small.

### Effects of the Invention

According to the electronic circuit device, the manufacturing method of the same and the display device of the present invention, the need for a high precision in placement of the adhesive materials of the first and second adhesive layers is eliminated. Less required precision allows for a shorter distance between the first and second electronic components, which can reduce the size of the electronic circuit device.

### BRIEF DESCRIPTION OF THE DRAWINGS

FIG. 1 is a schematic view of a mounting structure in the electronic circuit device according to Embodiment 1, wherein (a) is a schematic isometric view and (b) is a cross-sectional view taken along the line X-Y of FIG. 1(a).

FIGS. 2(a) to 2(d) are schematic isometric views of the electronic circuit device of Embodiment 1 in manufacturing steps.

FIG. 3 is a schematic view of another mounting structure in the electronic circuit device of Embodiment 1, wherein (a) is a schematic isometric view and (b) is a cross-sectional view taken along the line X-Y of FIG. 3(a).

FIG. 4 is a schematic isometric view of another mounting structure in the electronic circuit device of Embodiment 1.

FIG. 5 is a schematic view of a mounting structure in a conventional liquid crystal display panel, wherein (a) is a schematic isometric view and (b) is a cross-sectional view taken along the line P-Q of FIG. 6(a).

### DETAILED DESCRIPTION OF EMBODIMENTS

Embodiments of the present invention are described in detail below with reference to figures. The scope of the present invention, however, shall not be considered to be limited to those embodiments.

### Embodiment 1

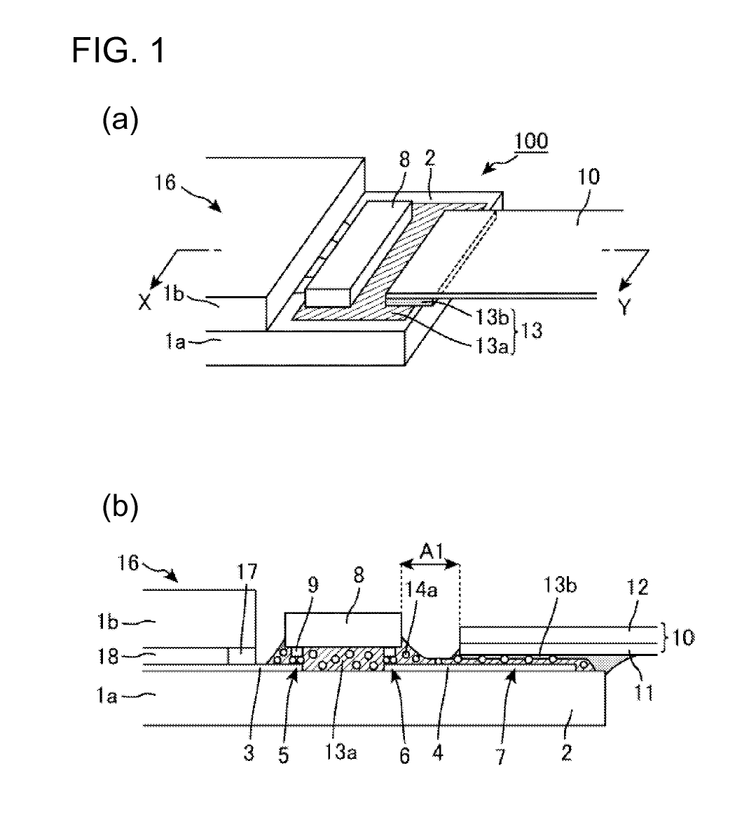

FIG. 1 is a schematic view of a mounting structure in the electronic circuit device according to Embodiment 1, wherein (a) is a schematic isometric view and (b) is a cross-sectional view taken along the line X-Y of FIG. 1(a).

As shown in FIG. 1, electronic circuit device 100 has liquid crystal display panel 16, which has substrate 1a as a third electronic component, driving IC 8 (a first electronic component) mounted on substrate 1a via adhesive layer 13 and flexible wiring substrate (FPC substrate) 10 (a second electronic component).

Liquid crystal panel 16 has a structure in which liquid crystal 18 is injected between substrates 1a and 1b (substrates constituting the panel) and sealed in by a sealing member 17. Normally, substrate 1a and substrate 1b serve as a TFT array substrate and a color filter substrate. Circuit wirings 3 and 4 are formed on substrate 1a on the side facing driving IC 8 and FPC substrate 10. Circuit wiring 3 has driving IC output pads 5 at the connection with driving IC 8. On the other hand, circuit wiring 4 has driving IC input pads 6 at the connection with driving IC 8, and FPC substrate connection pads 7 at the connection with the FPC substrate 10.

Driving IC 8 has bump electrodes 9, which are approximately 15 μm high, on the side facing substrate 1a. Bump electrodes 9 function as connection terminals of driving IC 8. Driving IC 8 is mounted, as a bare chip, on substrate 1a by COG (Chip-On-Glass) method. Driving IC 8 functions as a driver such as a gate driver or a source driver. Driving IC 8 therefore can be a device called COG chip, liquid crystal driver or driver IC. Of course, driving IC 8 can be an LSI.

The FPC substrate 10 has a base member 12 and lead electrodes 11 having a height of about 33 μm, formed on the side of the base member 12 facing substrate 1a. The lead electrodes 11 function as connection terminals of FPC substrate 10. Base member 12 is made of a resin such as polyimide. Base member 12 is a flexible film, and therefore, FPC substrate 10 can be bent. This allows further size reduction of electronic circuit device 100. IC (LSI) chips, such as controller IC and power supply IC, and electrical components, such as resistors and ceramic capacitors (not shown in the figures) may be mounted on the FPC substrate 10.

A continuous piece of anisotropic conductive layer 13a is disposed over the mounting areas of driving IC 8 and FPC substrate 10, covering the area where driving IC output pads 5, driving IC input pads 6 and FPC substrate connection pads 7 are placed. On the other hand, non-conductive layer 13b is disposed over the mounting area of the FPC substrate 10, covering the area at which FPC substrate connection pads 7 are placed. Suppose that a member on which electrical components are mounted (this is, the substrate 1a in this Embodiment) is in the “bottom” position, and the side away from the member on which electrical components are mounted is in the “top” position, adhesive layer 13 then has a two-layer structure of bottom anisotropic conductive layer 13a and top non-conductive layer 13b.

The anisotropic conductive layer 13a is an adhesive resin (more specifically, thermosetting resin such as epoxy resin) having storage elastic modulus of 1.5 to 2.0×10⁹ Pa, dispersed with particles having electrical conductivity (hereinafter may be referred to as “conductive particles”) 14a. Non-conductive layer 13b is an adhesive resin (more specifically, thermosetting resin such as epoxy resin) having a storage elastic modulus of 1.2 to 1.3×10⁹ Pa without any conductive particles. The diameter of conductive particles 14a is approximately 3 to 5 μm. The amount of conductive particles contained in the anisotropic conductive layer 13a is approximately 30 to 50×10³/mm². The conductive layer 13a is conductive in the direction of thickness (the direction normal to the substrate 1a), and is insulating in the direction of plane. By this anisotropic conductive material, bump electrodes 9 of the driving IC 8 are electrically connected to the driving IC output pads 5 and to the driving IC input pads 6 through the conductive particles 14a; and the driving IC 8 is bonded to the substrate 1a by thermal compression via resin contained in anisotropic conductive layer 13a. On the other hand, the lead electrodes 11 of FPC substrate 10 are electrically connected to the FPC substrate connection pads 7 through conductive particles 14a contained in anisotropic conductive layer 13a, and the FPC substrate 10 is bonded to substrate 1a by thermal compression via the resin contained in anisotropic conductive layer 13a and in the non-conductive layer 13b. In other words, two different adhesive layers—the anisotropic conductive layer 13a and the non-conductive 13b—are disposed between lead electrodes 11 of the FPC substrate 10 and the FPC electrode connection pads 7 of the substrate 1a.

The non-conductive layer 13b does not contain conductive particles, and therefore, is not conductive. The lead electrodes 11 are electrically connected to the FPC substrate connection pads 7 through the conductive particles 14a. By using non-conductive layer 13b, which does not contain conductive particles, manufacturing cost can be lowered and the thickness of non-conductive layer 13b can be reduced.

The storage elastic moduli of the anisotropic conductive layer 13a and of the non-conductive layer 13b are 1.5 to 2.0×10⁹ Pa and 1.2 to 1.3×10⁹ Pa, respectively. With these properties, the anisotropic conductive layer 13a and the non-conductive layer 13b present sufficient adhesion with the driving IC 8 and the FPC substrate 10, respectively.

The storage elastic modulus may be measured by conducting a dynamic elasticity test using Solid Analyzer RSA-2 (made by Rheometorics) as the measurement apparatus. Considering the limitation of the device, the frequency parameter should normally be set within a range of approximately 0.1 to 100 rad/sec.

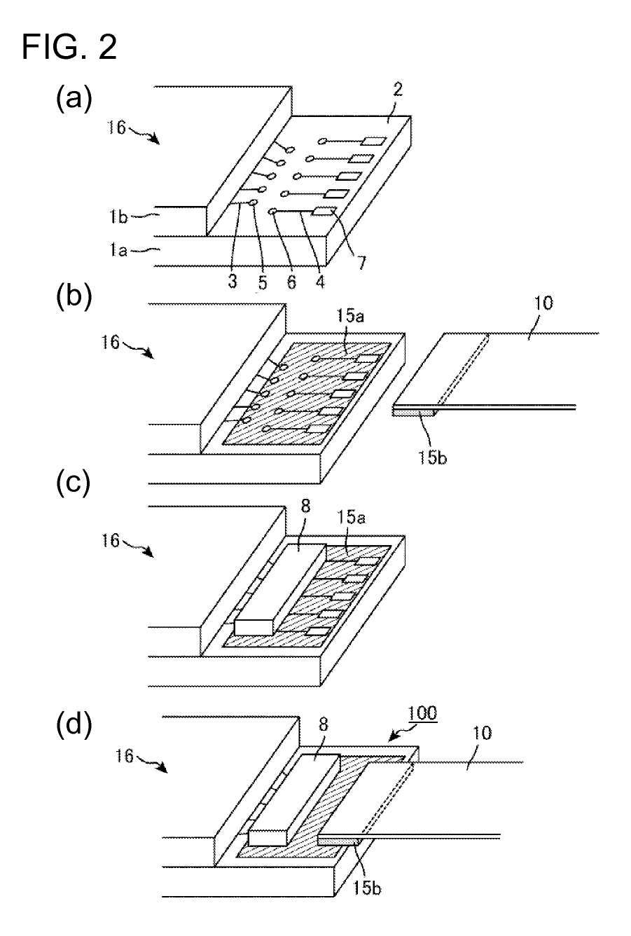

A method of manufacturing the electronic circuit device 100 is described below with reference to FIG. 2. FIGS. 2(a) to 2(d) are schematic isometric views of an electronic circuit device of Embodiment 1 in manufacturing steps.

As shown in FIG. 2(a), a liquid crystal display panel 16 with circuit wirings 3 and 4 formed on projected portion 2 of substrate 1a is prepared by a usual method. That is, various members, such as switching elements, bus wiring (gate wiring and source wiring) and pixel electrodes, are formed in a matrix form on substrate 1a inside the positioning area of sealing member 17 of an insulating substrate such as a glass substrate, and circuit wirings 3 and 4 are formed on the projected portion 2 of the insulating substrate. Normally, the substrate 1a is a TFT array substrate and the substrate 1b is a color filter substrate. Circuit wirings 3 and 4 are formed in the same wiring layer as a bus wiring. The circuit wiring 3 is connected to the bus wiring. The circuit wiring 3 may be formed with the bus wiring as a single piece. On the other hand, various members, such as a common electrode and a color filter layer, are formed on substrate 1b inside the positioning area of the sealing member 17 of the insulating substrate such as a glass substrate. Liquid crystal (e.g., nematic liquid crystal) 18 is sealed in between the substrates 1a and 1b by sealing member 17. The insulating substrate is usually made of glass, but may be made of transparent resin or the like.

Next, as shown in FIG. 2(b), anisotropic conductive film (ACF) 15a (the material of anisotropic conductive layer 13a before hardening) is applied to cover the mounting areas (the area containing circuit wirings 3 and 4) of the driving IC 8 and the FPC substrate 10 (this is the manufacturing step in which ACF 15a is applied). In a similar manner, a non-conductive film (NCF) 15b (the material of non-conductive layer 13b before hardening) is applied to cover the mounting area (the surface on which lead electrodes 11 are formed) of the FPC substrate 10 (this is the manufacturing step in which NCF 15b is applied). The ACF 15a is a film of a thermosetting resin such as epoxy with conductive particles 14a dispersed therein, and, the thickness of the film is preferably about 15-25 μm. When the thickness of ACF 15a is more than 25 μm, ACF 15a may not spread sufficiently, causing defective compression bonding. When the thickness is less than 15 μm, filling of ACF 15a may not be sufficient, causing poor connection reliability. NCF 15b is a film of a thermosetting resin such as epoxy that does not containe conductive particles. Preferably, the thickness of the film is about 10-20 μm. When the thickness of NCF 15b is more than 20 μm, NCF 15b may not spread sufficiently, causing defective compression bonding. When the thickness is less than 10 μm, filling of NCF 15b may not be sufficient, causing poor connection reliability.

In conventional technologies, the thickness of NCF 15b would normally be set at around 20 to 30 μm. In this Embodiment, as will be described later, ACF 15a is first applied over the area to which NCF 15b will be applied later. Therefore, the thickness of NCF 15b is set at a value obtained by subtracting the ACF 15a thickness from the conventional thickness. Controlling the thickness this way prevents poor connections caused by insufficient spread (insufficient push) due to excessive application of ACF 15a and/or NCF 15b. Preferably, the thickness of the adhesive material (NCF 15b in this Embodiment) applied for a single electronic component (the FPC substrate 10 in this Embodiment) is smaller than the thickness of the adhesive material (ACF 15a in this Embodiment) applied for at least two electronic components (the driving IC 8 and the FPC substrate 10 in this Embodiment).

NCF 15b may be applied over the substrate 1a on top of ACF 15a to cover the mounting area of FPC substrate 10.

Next, the driving IC 8 and the FPC substrate 10 are bonded by heat compression to liquid crystal display panel 16. First, the driving IC 8 is bonded by heat compression to liquid crystal panel 16. More specifically, as shown in FIG. 2(c), the driving IC output pads 5 and the driving IC input pads 6 are aligned to bump electrodes 9 of the driving IC 8, and then the driving IC 8 is bonded to circuit wirings 3 and 4 by thermal compression under predetermined parameters. Examples of the heat compression parameters include a compression temperature of 180 to 190° C., a compression time of 5 to 15 seconds and a pressure of 60 to 80 MPa. The mounting area of the driving IC 8 on the ACF 15a, and the surrounding area are hardened completely in this way. The mounting area of the FPC substrate 10 on ACF 15a, however, is left unhardened.

Preferably, the driving IC 8 is bonded by heat compression while the mounting area of the FPC substrate 10 on substrate 1a is being cooled by a cooling system (more specifically, cooled to approximately 80° C.). This reduces the extent of the hardened area around the driving IC 8 mounting area on the ACF 15a. The mounting area of the FPC substrate 10 can thus be closer to the mounting area of driving IC 8, which results in a smaller electronic circuit device 100. Also, the mounting area of the FPC substrate 10 can be left unhardened more reliably after the driving IC 8 is heat-bonded.

Next, the FPC substrate 10 is bonded by heat compression to liquid crystal panel 16. More specifically, as shown in FIG. 2(d), the lead electrodes 11 of the FPC substrate 10 are aligned with FPC substrate connection pads 7. While NCF 15b is positioned over ACF 15a, the FPC substrate 10 is bonded to circuit wiring 4 by thermal compression under predetermined parameters. Examples of heat compression parameters include a compression temperature of 180 to 190° C., a compression time of 10 to 20 seconds and a pressure of 1.5 to 2.5 MPa. Unhardened area on ACF 15a is now completely hardened together with ACF 15b. At this point, ACF 15a and NCF 15b do not need to be left unhardened. Therefore, there is no need to cool substrate 1a by a cooling system.

Preferably, the heat compression bonding of driving IC 8 and heat compression bonding of FPC substrate 10 are performed consecutively by utilizing multiple compressing devices or a single compressing device having multiple compressing units. This ensures that the mounting area of the FPC substrate 10 on ACF 15a remains unhardened before the FPC substrate 10 is mounted. For a faster operation with minimal interval between the processes, preferably a device such as a compressing device having multiple compressing units is utilized to perform consecutively the heat compression bonding of the driving IC 8 and the heat compression bonding of the FPC substrate 10.

Preferably, the heat compression bonding of the driving IC 8 and the compression bonding of the FPC substrate 10 are performed substantially simultaneously by utilizing a compressing device having multiple compressing units or the like. This makes the connection of the driving IC 8 and the FPC substrate 10 to liquid crystal display panel 16 more secure, improving the reliability of the electronic circuit device 100. Also, simultaneous bonding eliminates the need to add a cooling system to the compressing device, and thereby reduces the manufacturing cost. Heat compression bonding of driving IC 8 and FPC substrate 10 to the liquid crystal display panel 16 through unhardened ACF 15a and NCF 15b allows a shorter distance between the FPC substrate 10 mounting area and the driving IC 8 mounting area, which makes it possible to further reduce the size of the electronic circuit device 100. This way, the electronic circuit device 100 can be manufactured with ease.

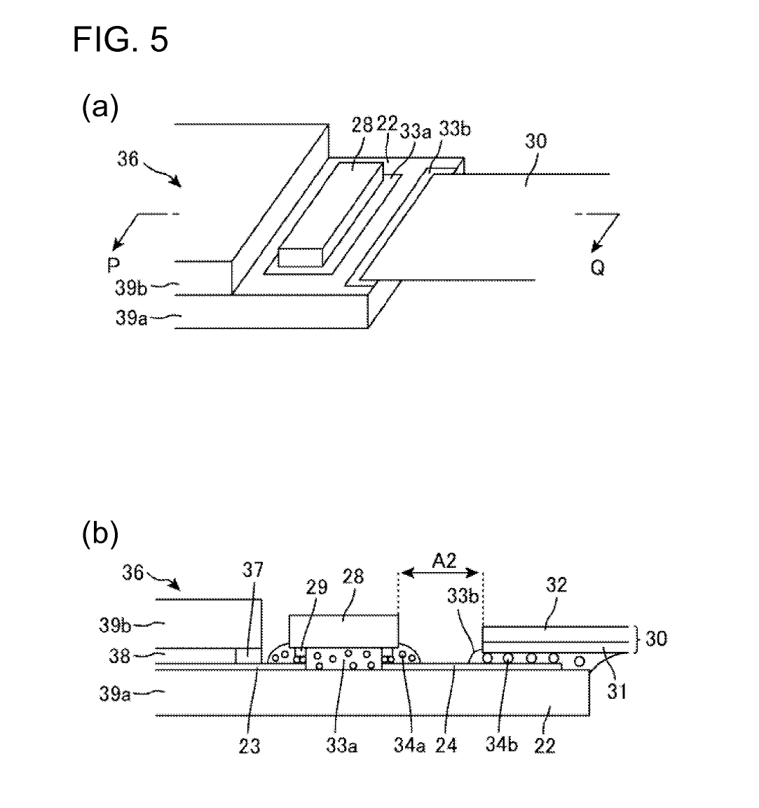

In the electronic device 100, the anisotropic conductive layer 13a and the non-conductive layer 13b are formed to cover the mounting area of the FPC substrate 10 in that order as seen the liquid crystal panel 16. Therefore, in determining the distance between the driving IC 8 and the FPC substrate 10 (space A1 in FIG. 1(b)), only mounting precision of electrical components such as driving IC 8 and FPC substrate 10, not positioning precision of ACF 15a and NCF 15b, needs to be considered. As a result, the distance A1 can be shorter than distance A2 in FIG. 5(b). Thus, the electronic circuit device 100 can be made more compact than conventional electronic circuit devices for which both ACF positioning precision and electronic component mounting precision have to be considered. This means that a display device such as a liquid crystal display device utilizing the electronic circuit device 100 can have a smaller frame area on the substrates constituting a panel, which makes the frame area of the display device narrower. By using non-conductive layer 13b, which does not contain conductive particles, manufacturing cost can be lowered and the thickness non-conductive layer 13b can be reduced.

Although ACF 15a is used to form anisotropic conductive layer 13a, and NCF 15b is used to form non-conductive layer 13b in this Embodiment, other adhesive materials may be used for anisotropic conductive layer 13a and non-conductive layer 13b. For example, an anisotropic conductive paste (ACP) or the like may be used to form the anisotropic conductive layer 13a, and a non-conductive paste (NCP) or the like may be used to form the non-conductive layer 13b.

The electronic circuit device 100 may have additional electronic components besides the driving IC 8 (first electronic component) and the FPC substrate 10 (second electronic component). Passive devices, such as LEDs, capacitors and sensors, may additionally be mounted on substrate 1a (third electronic component) through anisotropic conductive layer 13a or through both anisotropic conductive layer 13a and non-conductive layer 13b.

Although a liquid crystal display panel 16 having the projected portion 2 in a part of the substrate 1a is used in the description of the electronic circuit device 100, there is no specific limitation on locations of the projected portion 2, the driving IC 8 and of the FPC substrate 10. For example, the electronic circuit device 100 may have a substrate 1a having an L-shaped projected portion along two sides on which the driving IC 8 and the FPC substrate 10 are mounted, or may have substrates 1a and 1b both of which have a projected portion along a side on which driving IC 8 and FPC substrate 10 are mounted.

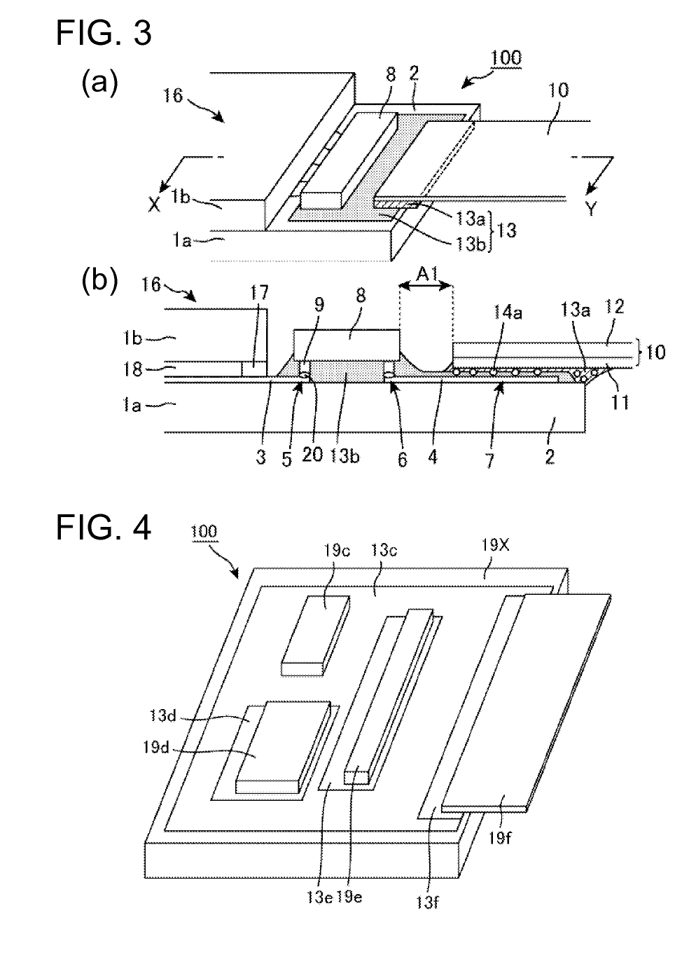

In this Embodiment, anisotropic conductive layer 13a is disposed over the mounting areas of the driving IC 8 and the FPC substrate 10, and non-conductive layer 13b is disposed over the mounting area of the FPC substrate 10. Anisotropic conductive layer 13a and non-conductive layer 13b, however, may be exchanged. In other words, non-conductive layer 13b may be disposed over the mounting areas of the driving IC 8 and the FPC substrate 10, and anisotropic conductive layer 13a may be disposed over the mounting area of the FPC substrate 10. In this case, there are no conductive particles 14a in the mounting area of driving IC 8, and therefore, the bump electrodes 9 need to be electrically connected to the driving IC output pads 5 and to the driving IC input pads 6 in another way. For this purpose, for example, Au-plated bump electrodes 9, Sn-plated driving IC output pads 5 and Sn-plated driving IC input pads 6 may be used. FIG. 3 is a schematic view of another mounting structure in the electronic circuit device according to Embodiment 1, wherein (a) is a schematic isometric view and (b) is a cross-sectional view taken along the line X-Y of FIG. 3(a). Driving IC 8 and FPC substrate 10 are mounted on display panel 16 as follows: first, an NCP is applied over the mounting areas of the driving IC 8 and the FPC substrate 10, then the driving IC 8 is pressed against the display panel 16 under a pressure. This action pushes out the NCP located between the bump electrodes 9 and the driving IC output pads 5 and between the bump electrodes 9 and the driving IC input pads 6. Pressure is applied until the bump the electrodes 9 come into contact with the driving IC output pads 5 and with the driving IC input pads 6. While the pressure is applied, the mounting area of driving IC 8 is heated to approximately 400° C. Au (gold)-Su (tin) eutetic 20 is formed by the heating at the contact point between the Au-plated bump electrodes 9 and the Sn-plated driving IC output pads 5 and at the contact point between the bump electrodes 9 and the Sn-plated driving IC input pads 6. Bump electrodes 9 are electrically connected to the driving IC output pads 5 and to the driving IC input pads 6 through the Au—Sn eutectic 20. Then, ACF is applied to cover the mounting area of the FPC substrate 10 (the surface on which lead electrodes 11 are formed), and the FPC substrate 10 is bonded to the liquid crystal panel 16 by heat compression through NCP and ACF. In this embodiment, an NCF may be disposed over the mounting areas of the driving IC 8 and the FPC substrate 10. Preferably, however, an NCP is disposed to facilitate the connection between the bump electrodes 9 and the driving IC output pads 5 and between the bump electrodes 9 and the driving IC input pads 6.

In embodiments in which non-conductive layer 13b is disposed over the mounting areas of the driving IC 8 and the FPC substrate 10, and anisotropic conductive layer 13a is disposed over the mounting area of the FPC substrate 10, bump electrodes 9 may contain resins in a particulate form, such as styrene resin and acrylic resin. Such bump electrodes 9 can be formed, for example, by dispersion plating, which is electrolytic plating performed while the electrolyte containing the resin particles is being agitated. The resin particles contained in the bump electrodes 9 increases the amount of elastic deformation of the bump electrodes 9. Stable contact between the bump electrodes 9 and the driving IC output pads 5 and between the bump electrodes 9 and the driving IC input pads 6 can be achieved by the elastic recovery property of the bump electrodes 9, whereby electrical connection between the bump electrodes 9 and the driving IC output pads 5 and between the bump electrodes 9 and the driving IC input pads 6 can be established. In this case, the driving IC 8 and the FPC substrate 10 are mounted on display panel 16 as follows: first, an NCP is applied over the mounting areas of the driving IC 8 and the FPC substrate 10, then the driving IC 8 is pressed against the display panel 16 under a pressure. This action pushes out the NCP located between the bump electrodes 9 and the driving IC output pads 5 and between the bump electrodes 9 and the driving IC input pads 6. Pressure is applied until the bump electrodes 9 come into contact with the driving IC output pads 5 and with the driving IC input pads 6. While the pressure is applied, the mounting area of driving IC 8 is heated. This allows the driving IC 8 to be mounted to the display panel 16. Then, an ACF is applied to cover the mounting area of the FPC substrate 10 (the surface on which lead electrodes 11 are formed), and the FPC substrate 10 is bonded to liquid crystal panel 16 by heat compression through the NCP and the ACF.

In this Embodiment, only one of the driving IC and the FPC substrate is mounted by 2 adhesive layers of different kinds In the present invention, however, there is no specific limit to the number of electronic components to be mounted by multiple anisotropic conductive layers, and therefore, 2 or more electronic components may be mounted. FIG. 4 is a schematic isometric view of another mounting structure in the electronic circuit device according to Embodiment 1. As shown in FIG. 4, the electronic circuit device 100 in this Embodiment have a structure in which an electronic component 19c is bonded to a receiving component (electronic component 19X) through anisotropic conductive layer 13c; an electronic component 19d is bonded to the electronic component 19X through the anisotropic conductive layer 13c and a non-conductive layer 13d, disposed in this order on the electronic component 19X; an electronic component 19e is bonded to the electronic component 19X through the anisotropic conductive layer 13c and a non-conductive layer 13e, disposed in this order on the electronic component 19X; an electrical component 19f is bonded to the electronic component 19X through the anisotropic conductive layer 13c and a non-conductive layer 13f, disposed in this order on the electronic component 19X; and the electronic component 19c, the electronic component 19d, the electronic component 19e and the electronic component 19f are electrically connected through anisotropic conductive layer 13c.

Electronic circuit device 100 shown in FIG. 4 may be manufactured, for example, by the following process: the material for anisotropic conductive layer 13c (e.g., an anisotropic conductive film) is applied on the receiving component (electronic component 19X) to cover the mounting areas of electronic component 19c, the electronic component 19d, electronic component 19e and electronic component 19f. Next, the material for non-conductive layer 13d (e.g., a non-conductive film), the material for non-conductive layer 13e (e.g., a non-conductive film) and the material for non-conductive layer 13f (e.g., a non-conductive film) are applied in this order. Then, electronic component 19c, electronic component 19d, electronic component 19e and electronic component 19f are consecutively bonded to electronic component 19X by heat compression.

In Embodiment 1, the present invention is described as a device for use in a liquid crystal display device. The electronic circuit device of the present invention, however, may be used not only in a liquid crystal display device but also in various display devices, such as organic electroluminescence (EL) display device, inorganic EL display device, plasma display panel (PDP), vacuum fluorescent display (VFD) device and electronic paper. The electronic circuit device of the present invention is also applicable to a variety of electronic devices, such as portable phones, PDA (Personal Digital Assistant), office automation devices and personal computers. That is, the present invention may be utilized in embodiments in which two ICs are mounted on a FPC substrate or an IC and a FPC substrate are mounted on a PWB through a multi-layer adhesive layer comprising non-conductive layers, through a multi-layer adhesive layer comprising a non-conductive layer and an anisotropic conductive layer or through a multi-layer adhesive layer comprising anisotropic conductive layers.

The present application claims priority to Patent Application No. 2008-188636 filed in Japan on Jul. 22, 2008 under the Paris Convention and provisions of regional laws in designated States, the entire contents of which are hereby incorporated by reference.

### DESCRIPTION OF REFERENCE NUMERALS

1a, 1b Substrate

2, 22 Projected portion

3, 4, 23, 24 Circuit wiring

5 Driving IC output pad

6 Driving IC input pad

7 FPC substrate connection pad

8, 28 Driving IC

9, 29 Bump electrode

10, 30 FPC substrate

11, 31 Lead electrode

12, 32 Member

13 Adhesive layer

13a, 13c, 33a, 33b Anisotropic conductive layer

13b, 13d, 13e, 13f Non-conductive layer

14a, 34a, 34b Conductive particles (particles having conductivity)

15a Anisotropic conductive film (ACF)

15b Non-conductive film (NCF)

16, 36 Liquid crystal display panel

17, 37 Sealing member

18, 38 Liquid crystal

19c, 19d, 19e, 19f, 19X Electronic component

20 Au—Sn eutectic

39a, 39b Glass substrate

100 Electronic circuit device

A1, A2 Distance between driving IC and FPC substrate (space)

1. An electronic circuit device comprising a first electronic component and a second electronic component which are respectively connected to a third electronic component electrically,
wherein the first electronic component is bonded to the third electronic component through a first adhesive layer,
wherein the second electronic component is bonded to the third electronic component through the first adhesive layer and a second adhesive layer, and
wherein one of the first adhesive layer and the second adhesive layer contains an anisotropic conductive material and the other does not contain the anisotropic conductive material.

2. The electronic circuit device according to claim 1, wherein the first adhesive layer contains the anisotropic conductive material, and the second adhesive layer does not contain the anisotropic conductive material.

3. The electronic circuit device according to claim 1, wherein the first adhesive layer does not contain the anisotropic conductive material, and the second adhesive layer contains the anisotropic conductive material.

4. The electronic circuit device according to claim 1, wherein the first electronic component and the second electronic component are electronic components of different kinds.

5. The electronic circuit device according to claim 1, wherein the third electronic component is a wiring substrate.

6. The electronic circuit device according to claim 1, wherein the first electronic component has different surface properties from the second electronic component.

7. The electronic circuit device according to claim 1, wherein the first electronic component and the second electronic component are a combination of a semiconductor element and a flexible printed circuit substrate, and the third electronic component is a substrate that constitutes a part of a panel.

8. The electronic circuit device according claim 1, wherein the first adhesive layer and the second adhesive layer individually contain different kinds of adhesive material.

9. The electronic circuit device according to claim 1, wherein the first adhesive layer and the second adhesive layer have different storage elastic moduli.

10. The electronic circuit device according to claim 1, wherein the first adhesive layer and the second adhesive layer are a combination of an adhesive layer having a storage elastic modulus of 1.5 to 2.0×10⁹ Pa and an adhesive layer having a storage elastic modulus of 1.2 to 1.3×10⁹ Pa.

11. The electronic circuit device according to claim 1, wherein the first electronic component is a semiconductor element,
wherein the second electronic component is a flexible printed circuit substrate, the third electronic component is a substrate that constitute a part of a panel, the first adhesive layer has a storage elastic modulus of 1.5 to 2.0×10⁹ Pa, and the second adhesive layer has a storage elastic modulus of 1.2 to 1.3×10⁹ Pa.

12. The electronic circuit device according to claim 1, wherein at least one of the first adhesive layer and the second adhesive layer is formed of a film.

13. The electronic circuit device according to claim 1, wherein the first adhesive layer has a larger thickness than the second adhesive layer.

14. A manufacturing method for the electronic circuit device according to claim 1, comprising the steps of:
applying the first adhesive material on the third electronic component to cover the mounting areas of the first electronic component and the second electronic component,
applying the second adhesive material to cover the mounting area of the second electronic component on the third electronic component, or to cover an area on the second electronic component to be bonded to the third electronic component,
performing a first compression bonding process, whereby the first electronic component is compression bonded to the third electronic component through the first adhesive material, and
performing a second compression bonding process, whereby the second electronic component is compression bonded to the third electronic component through the second adhesive material.

15. The manufacturing method for the electronic circuit device according to claim 14,
wherein the first compression bonding process is a first thermal compression bonding process whereby the first electronic component is bonded to the third electronic component by thermal compression through the first adhesive material, and
wherein the second compression bonding process is a second thermal compression bonding process whereby the second electronic component is bonded to the third electronic component by thermal compression through the first adhesive material and the second adhesive material.

16. The manufacturing method for the electronic circuit device according to claim 15, wherein the first thermal compression bonding process and the second thermal compression bonding process are performed consecutively.

17. The manufacturing method for the electronic circuit device according to claim 15, wherein the first thermal compression bonding process or the second thermal compression bonding process, whichever performed later, is performed while at least one of the first adhesive material and the second adhesive material disposed over an area to which the first electronic component or the second electronic component is to be bonded by thermal compression is still unhardened.

18. The manufacturing method for the electronic circuit device according to claim 15, wherein either the first thermal compression bonding process or the second thermal compression bonding process, whichever performed earlier, is performed while the area on the third electronic component to which the first electronic component or the second electronic component is to be bonded in the first thermal compression bonding process or the second thermal compression bonding process, whichever performed later, is being cooled.

19. The manufacturing method of the electronic circuit device according to claim 15, wherein the first thermal compression bonding process and the second thermal compression bonding process are performed simultaneously.

20. The manufacturing method of the electronic circuit device according to claim 15, wherein the first adhesive material has a larger thickness than the second adhesive material.

21. A display device having the electronic circuit device according to claim 1.

22. A display device having the electronic circuit device manufactured by the manufacturing method according to claim 14.
